(19) United States
(12) Patent Application Publication
(10) Pub. No.: US 2002/0145163 A1
(43) Pub. Date: Oct. 10, 2002

(54) Electrostatic discharge protection apparatus

(76) Inventor: Jui-Hsiang Pan, Hsinchu (TW)

Correspondence Address: J C Patents Inc, 4 VENTURE, SUITE 250, Irvine, CA, 92618, US

(21) Appl. No.: 09/515,165

(22) Filed: Feb. 29, 2000

(51) Int. Cl. H01L 23/62

(52) U.S. Cl. 257/355

(57) ABSTRACT

An electrostatic discharge protection apparatus. Drift regions of source regions and drain regions in the conventional PMOS transistor and NMOS transistor are removed to avoid spike discharge. In addition, a P-type pocket region are formed at peripheries of the drain region and the source region of an NMOS transistor, and N-type pocket regions are formed at peripheries of the drain region and the source region of a PMOS transistor.

### BACKGROUND OF THE INVENTION

1. Field of the Invention

The invention relates in general to an electrostatic discharge (ESD) protection apparatus. More particularly, this invention relates to an electrostatic discharge apparatus that is applicable for a high voltage device.

2. Description of the Related Art

In a fabrication process of an integrated circuit (IC) such as a dynamic random access memory (DRAM) or a static random access memory (SRAM), or after the chip is fabricated, the electrostatic discharge is the major cause to damage the integrated circuit. For example, when a human being walking on a blanket, in an environment with a high relative humidity (HR), the human being may carry from hundreds to thousands of electrostatic voltages. When the relative humidity is low, more than ten thousand of electrostatic voltages may be carried. In case the carried electrostatic charges are in contact with the chip, the chip is easily damaged to malfunction. To avoid the electrostatic discharge damage, various electrostatic protection methods or apparatus are developed. A very common type of electrostatic protection is to design an on-chip electrostatic discharge protection circuit between the internal circuit and each pad.

FIG. 1 shows a circuit diagram of a conventional electrostatic discharge protection apparatus. In FIG. 1, electrostatic charges input from an I/O port can be discharged to a ground line Vss via an N-type metal-oxide semiconductor (NMOS) 10, or discharged to a voltage source Vdd via a P-type metal-oxide semiconductor (PMOS) 12, followed by being input to a buffer 14.

In such an electrostatic discharge protection apparatus as shown in FIG. 1, the PMOS 12 comprises a P-type grade region and a P-type drifting region extending from both the source region and the drain region to a portion of the channel region under the gate thereof. Similarly, the NMOS 10 also comprises an N-type grade region and a P-type drifting region extending from the source region and the drain region to a portion of the channel region under the gate thereof.

For a high voltage device, the junction breakdown voltages (Ju BV) of the junction between N-type grade region and a P-well that contains this NMOS 10 and of the junction between the P-type grade region and an N-well that contains the PMOS 12 have to be increased. An I-V characteristic of a bipolar junction transistor (BJT) induced at a CMOS transistor is shown in FIG. 2. As the breakdown voltage is increased, the time to the induced bipolar junction transistor to be conducted is longer. As a result, the junction between the drain region and the well is easily to enter a second breakdown point denoted as 78 to cause malfunction of the device.

In addition, the drifting regions extending from the source and drain region to portions of the channel region easily cause spike discharge. The electrostatic discharge protection performance is thus greatly affected. While a large current is input, the source region and the drain region may even be short circuit.

### SUMMARY OF THE INVENTION

The invention provides an electrostatic discharge (ESD) protection apparatus. A P-well and an N-well adjacent to the N-well are formed on a substrate. A first isolation region is at a junction between the P-well and the N-well. An NMOS transistor in the P-well comprises a source region and a drain region having the structures of an N+ region, an N-type grade region at a periphery of the N+ region and a P-type pocket region at a periphery of the N-type grade region. A PMOS transistor in the N-well comprises a source region and a drain region having the structures of a P+ region, a P-type grade region at a periphery of the P+ region and an N-type pocket region at a periphery of the P-type grade region.

The PMOS transistor comprises further a gate, the gate and the source region are coupled to a high voltage, and the drain region is coupled to an I/O pin. The NMOS transistor comprises further a gate, the gate and the source region are coupled to a ground voltage, and the drain region is coupled to an I/O pin.

Thus designed, the drifting regions in the conventional electrostatic discharge protection apparatus are replaced by the structures of the pocket regions, so that the spike discharge is avoided. In addition, the structure of P-type pocket region/N-type grade region/N+ region or N-type pocket region/P-type grade region/P+ region has an reduced junction breakdown voltage, so that the conducting time for this device is greatly shortened.

Both the foregoing general description and the following detailed description are exemplary and explanatory only and are not restrictive of the invention, as claimed.

### BRIEF DESCRIPTION OF THE DRAWINGS

FIGS. 1 shows a circuit diagram of a conventional electrostatic discharge protection apparatus;

FIG. 2 shows an I-V characteristic of a bipolar junction transistor (BJT) induced at a CMOS transistor; and

FIG. 3 shows a cross sectional structure of an electrostatic discharge protection apparatus applied to a high voltage device according to the invention.

### DESCRIPTION OF THE PREFERRED EMBODIMENTS

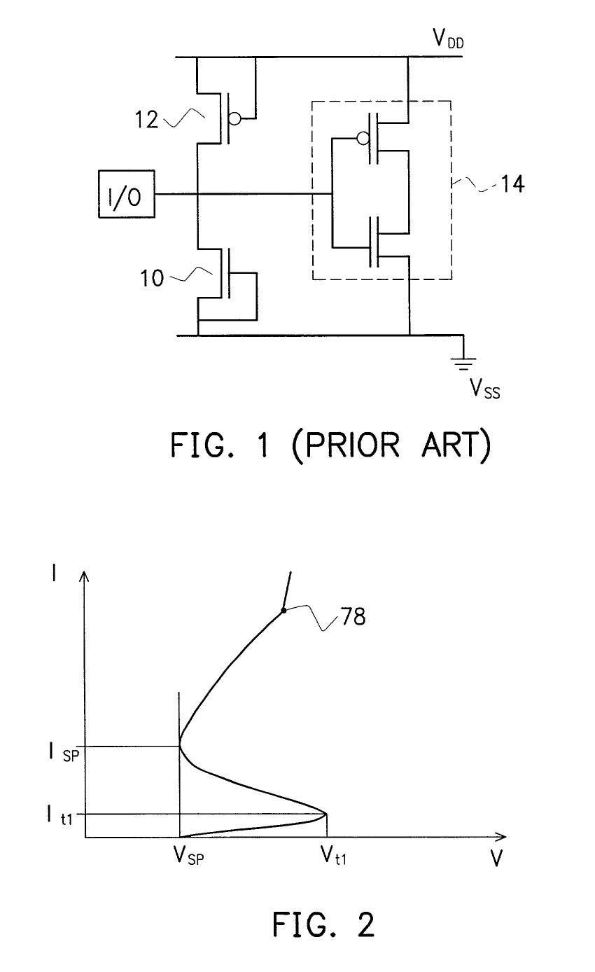

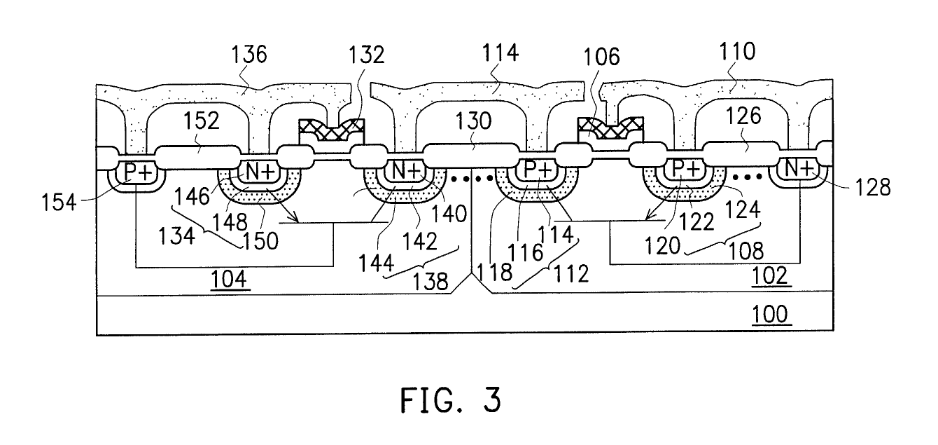

In FIG. 3, in a high voltage device, an electrostatic discharge protection apparatus is formed on an N-type substrate 100. A high voltage N-well 102 and a high voltage P-well 104 are formed on the N-type substrate. A PMOS transistor (corresponding to the PMOS 12 in FIG. 1) is formed on the high voltage N-well 102, and an NMOS transistor (corresponding to the NMOS 10 as shown in FIG. 1) is formed on the high voltage P-well 104. The PMOS transistor comprises a gate 106 and a source region 108 coupled to a high voltage Vdd via a metal line 110, and a drain region 112 coupled to an I/O pin via a metal line 114.

The drain region 112 comprises a P+ (heavily doped P-type) region 114, a P-type grade region 116 surrounding the P+ region 114 in the high voltage N-well 102, and an N-type pocket region 118 surrounding the P-type grade region 116 in the high voltage N-well 102. Similarly, the source region 108 of the PMOS transistor comprises a P+ region 120, a P-type grade region 122 at a periphery of the P+ reigon 120, and an N-type pocket region 124 at a periphery of the P-type grade region 122.

In addition, the high voltage N-well 102 comprises further an isolation region 126 next to the source region 108, an N+ substrate connecting region 128 at an edge thereof.

In the high voltage P-well 104, the NMOS transistor comprises a gate 132 and a source region 134 coupled to the ground voltage Vss via a metal line 136, and a drain region 138 coupled to the I/O pin via the metal line 114. The drain region 138 comprises a (heavily doped N-type) N+ region 140, a N-type grade region 142 at a periphery of the N+ region 140 and a P-type pocket region 144 at a periphery of the N-type grade region 142. Between the high voltage P-well 104 and the high voltage N-well 102, an isolation region 130 is formed. In this embodiment, the isolation region 130 is between the drain region 138 of the NMOS transistor and the drain region 112 of the PMOS transistor. The source region 134 comprises an N+ region 146, an N-type grade region 148 around the N+ region 146 and a P-type pocket region 150 surrounding the N-type grade region 148.

In addition to the above elements, the high voltage P-well 104 comprises further an isolation region 152 next to the source region 134. At an edge of the high voltage P-well 104 and next to the isolation region 152, a P+ region 154 is formed to couple to a ground voltage Vss.

Comparing to the conventional electrostatic discharge protection apparatus, the drifting regions is replaced by forming the pocket region with a conductive type opposite to that source/drain region being surrounded thereby. Therefore, the spike discharge can be avoided. In addition, the structure of P-type pocket region/N-type grade region/N+ region or N-type pocket region/P-type grade region/P+ region has an reduced junction breakdown voltage, so that the conducting time for this device is greatly shortened.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. An electrostatic discharge protection apparatus, comprising:
a P-well;
an N-well adjacent to the P-well;
a first isolation region at a junction between the P-well and the N-well;
an NMOS transistor in the P-well, the NMOS transistor comprising a source region and a drain region having the structures of:
an N+ region;
an N-type grade region at a periphery of the N+ region; and
a P-type pocket region at a periphery of the N-type grade region; and
a PMOS transistor in the N-well, wherein the PMOS comprises a source region and a drain region having the structures of:
a P+ region;
a P-type grade region at a periphery of the P+ region; and
an N-type pocket region at a periphery of the P-type grade region.

2. The protection apparatus according to claim 1, wherein the PMOS transistor comprises further a gate, the gate and the source region are coupled to a high voltage, and the drain region is coupled to an I/O pin.

3. The protection apparatus according to claim 1, wherein the NMOS transistor comprises further a gate, the gate and the source region are coupled to a ground voltage, and the drain region is coupled to an I/O pin.

4. The protection apparatus according to claim 1, wherein the N-well comprises further a second isolation region next to the source region of the PMOS transistor.

5. The protection apparatus according to claim 1, wherein the N-well comprises further an N+ region at an edge thereof.

6. The protection apparatus according to claim 1, wherein the P-well comprises further a third isolation region next to the source region of the NMOS transistor.

7. The protection apparatus according to claim 1, wherein the P-well comprising further a P+ region at an edge thereof.

8. The protection apparatus according to claim 1, wherein the N-well and the P-well are formed on an N-type substrate.

9. An electrostatic discharge protection apparatus, comprising an NMOS transistor in a P-well and a PMOS transistor in an N-well, wherein each of a source region and a drain region of the NMOS comprises an N-type grade region and a P-type pocket region, and each of a source region and a drain region of the PMOS comprises a P-type grade region and an N-type pocket region.
